(19) United States
(12) Patent Application Publication
(10) Pub. No.: US 2025/0357114 A1
(43) Pub. Date: Nov. 20, 2025

(54) METHOD OF FORMING LOW-K MATERIAL LAYER, STRUCTURE INCLUDING THE LAYER, AND SYSTEM FOR FORMING SAME

(71) Applicant: ASM IP Holding B.V., Almere (NL)

(72) Inventor: Chie Kaneko, Tama, Tokyo (JP)

(21) Appl. No.: 19/283,552

(22) Filed: Jul. 29, 2025

Related U.S. Application Data
(62) Division of application No. 17/182,321, filed on Feb. 23, 2021.
(60) Provisional application No. 62/981,219, filed on Feb. 25, 2020.

(51) Int. Cl. H01L 21/02; C23C 16/50; C23C 16/56

(52) U.S. Cl. CPC H01L 21/0234; C23C 16/50; C23C 16/56; H01L 21/02274; H01L 21/02348; H01L 21/02211; H01L 21/02216

(57) ABSTRACT

Methods and systems for forming a cured low-k material layer on a surface of a substrate and structures and devices formed using the method or system are disclosed. Exemplary methods include providing a substrate within a reaction chamber of a reactor system, providing one or more precursors to the reaction chamber, providing plasma power to polymerize the one or more precursors, and curing the low-k material with activated species to form the cured low-k material layer.

### CROSS-REFERENCE TO RELATED APPLICATIONS

This application is a divisional of, and claims priority to, U.S. patent application Ser. No. 17/182,321 filed Feb. 23, 2021 titled METHOD OF FORMING LOW-K MATERIAL LAYER, STRUCTURE INCLUDING THE LAYER, AND SYSTEM FOR FORMING SAME; which claims priority to U.S. Provisional Application No. 62/981,219 filed Feb. 25, 2020, titled METHOD OF FORMING LOW-K MATERIAL LAYER, STRUCTURE INCLUDING THE LAYER, AND SYSTEM FOR FORMING SAME, the disclosures of which are hereby incorporated by reference in their entirety.

### FIELD OF INVENTION

The present disclosure generally relates to methods of forming layers and structures suitable for use in the manufacture of electronic devices. More particularly, examples of the disclosure relate to methods of forming low dielectric constant material layers, to structures and devices including such layers, and to systems for performing the methods and/or forming the structures and/or devices.

### BACKGROUND OF THE DISCLOSURE

During the manufacture of devices, such as semiconductor devices, it is often desirable to deposit a low dielectric constant (low-k) material—e.g., to fill features (e.g., trenches or gaps)-on the surface of a substrate. By way of examples, low-k material can be used as an intermetal dielectric layer on patterned metal features, a gap fill in back-end-of-line processes, insulating layers, or for other applications.

Some techniques for forming low-k material include depositing material and using ultraviolet (UV) light to cure the deposited material. Although these techniques can work well for some applications, use of UV light to cure the deposited material can have several shortcomings, particularly as the size of the features to be filled decreases. For example, a surface of the deposited material can become damaged and/or a porosity of the deposited material can increase during a step of curing the deposited material using UV light. In addition, curing using UV light is generally an anisotropic process, which can be problematic when curing deposited material on or within features. Accordingly, improved methods for forming low-k material layers on a surface of a substrate are desired.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY OF THE DISCLOSURE

Various embodiments of the present disclosure relate to methods of forming a cured low-k material layer on a surface of a substrate, to structures including the cured low-k material layer, and to systems for performing the methods and/or forming the structures. While the ways in which various embodiments of the present disclosure address drawbacks of prior methods and structures are discussed in more detail below, in general, exemplary embodiments of the disclosure use activated species formed using a plasma to cure deposited low-k material.

In accordance with various embodiments of the disclosure, methods of forming a cured low-k material layer on a surface of a substrate are provided. Exemplary methods include the steps of providing a substrate within a reaction chamber of a reactor system, providing one or more precursors to the reaction chamber, providing plasma power to polymerize the one or more precursors within the reaction chamber to form low-k material, and curing the low-k material with activated species to form the cured low-k material layer. A temperature (e.g., a substrate temperature) within the reaction chamber during the step of providing one or more precursors to the reaction chamber can be between about 340° C. and about 395° C., or about 250° C. and about 500° C., or about 300° C. and about 395° C. A pressure within the reaction chamber during the step of providing one or more precursors to the reaction chamber can be between about 700 Pa and about 900 Pa or about 200 Pa and about 1,000 Pa. A power to produce the plasma during the step of providing plasma power to polymerize the one or more precursors can be between about 500 W and about 2,000 W or about 600 W and about 2,500 W. A frequency of the power to produce the plasma during the step of providing plasma power to polymerize the one or more precursors can be between about 400 kHz and about 27.12 MHz or about 400 kHz and about 60 MHz. The one or more precursors can include a compound comprising one or more of Si—C—Si and Si—O—Si bonds. The compounds can include linear and/or cyclic structures. The step of curing can use of one or more of a capacitively coupled plasma (CCP) excitation, RF frequency excitation, inductively coupled plasma (ICP) excitation, microwave excitation, and very high frequency (VHF) (e.g., VHF CCP) excitation of an inert gas to form the activated species. A temperature (e.g., a substrate temperature) within the reaction chamber during the step of curing the material with activated species can be between about 370° C. and about 410° C., about 300° C. and about 500° C., or about 370° C. and about 410° C. A pressure within the reaction chamber during the step of curing the material with activated species can be between about 300 Pa and about 800 Pa or about 200 Pa and about 1,000 Pa. A power to produce the plasma during the step of curing the material with activated species can be between about 500 W and about 2,000 W or about 600 W and about 2,500 W. A frequency of the power to produce the activated species during the step of curing the material with activated species can be between about 400 kHz and about 27.12 MHz or about 400 kHz and about 5 GHZ. Exemplary methods can also include a step of providing an inert gas to the reaction chamber, wherein the step of providing the inert gas overlaps in time with the step of providing one or more precursors to the reaction chamber.

In accordance with yet further exemplary embodiments of the disclosure, a structure is formed, at least in part, according to a method described herein. The structure can include a cured low-k material layer. The dielectric material layer can be deposited over features having an aspect ratio of, for example, 1:1 or more.

In accordance with further examples of the disclosure, a device can be formed using a method and/or include a structure as described herein.

In accordance with yet further exemplary embodiments of the disclosure, a system is provided for performing a method and/or for forming a structure as described herein.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a method in accordance with exemplary embodiments of the disclosure.

FIG. 2 illustrates exemplary embodiments as deposited and cured low-k material layer properties in accordance with embodiments of the disclosure.

FIG. 3 illustrates exemplary process conditions in accordance with embodiments of the disclosure.

FIG. 4 illustrates elastic modulus and dielectric constant values of as deposited and cured low-k material layer properties in accordance with embodiments of the disclosure.

FIG. 5 illustrates leakage current density and electric field measurements of as deposited and cured low-k material layers in accordance with embodiments of the disclosure.

FIG. 6 illustrates absorbance measurements of as deposited and cured low-k material layers in accordance with embodiments of the disclosure.

FIG. 7 illustrates structures in accordance with embodiments of the disclosure.

FIG. 8 illustrates a polymerization process in accordance with examples of the disclosure.

FIG. 9 illustrates quantitative analysis of FTIR spectrum by peak fitting and peak area calculation of as deposited and cured low-k material layers in accordance with embodiments of the disclosure.

FIG. 10 illustrates FITR Spectra of cured low-k material layers in accordance with embodiments of the disclosure.

FIG. 11 illustrates benefits of plasma cure vs UV lamp cure in accordance with embodiments of the disclosure.

FIG. 12 illustrates a process sequence diagram in accordance with embodiments of the disclosure.

FIG. 13 illustrates a reactor system for forming low-k material and/or cured low-k material layers in accordance with embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The present disclosure generally relates to methods of forming a cured low-k material layer on a surface of a substrate, to methods of forming structures and devices, to structures and devices formed using the methods, and to systems for performing the methods and/or forming the structures and devices. By way of examples, the methods described herein can be used to fill features, such as gaps (e.g., trenches or vias) on a surface of a substrate with the cured low-k material. The terms gap and recess can be used interchangeably.

In this disclosure, “gas” can refer to material that is a gas at normal temperature and pressure, a vaporized solid and/or a vaporized liquid, and may be constituted by a single gas or a mixture of gases, depending on the context. A gas other than a process gas, i.e., a gas introduced without passing through a gas distribution assembly, such as a showerhead, other gas distribution device, or the like, may be used for, e.g., sealing a reaction space, which includes a seal gas, such as a rare gas. In some cases, such as in the context of deposition of material, the term “precursor” can refer to a compound that participates in the chemical reaction that produces another compound, and particularly to a compound that constitutes a film matrix or a main skeleton of a film. The term “inert gas” refers to a gas that does not take part in a chemical reaction to an appreciable extent and/or a gas that excites a precursor (e.g., to facilitate polymerization of the precursor) when, for example, power (e.g., RF power) is applied, but it may not become a part of a film matrix to an appreciable extent. Exemplary inert gases include argon, helium, nitrogen, and neon, and any mixture thereof.

As used herein, the term “substrate” can refer to any underlying material or materials that may be used to form, or upon which, a device, a circuit, or a film may be formed. A substrate can include a bulk material, such as silicon (e.g., single-crystal silicon), other Group IV materials, such as germanium, or compound semiconductor materials, such as Group III-V or Group II-VI semiconductors, and can include one or more layers overlying or underlying the bulk material. Further, the substrate can include various features, such as gaps (e.g., recesses or vias), lines or protrusions, such as lines having gaps formed therebetween, and the like formed on or within at least a portion of a layer or bulk material of the substrate. By way of examples, one or more features can have a width of about 10 nm to about 100 nm, a depth or height of about 30 nm to about 1,000 nm, and/or an aspect ratio of about 1:1, 1:3, 1:10, 1:100, or more.

In some embodiments, “film” refers to a layer extending in a direction perpendicular to a thickness direction. In some embodiments, “layer” refers to a material having a certain thickness formed on a surface and can be a synonym of a film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. The layer or film can be continuous—or not. Further, a single film or layer can be formed using one or more deposition cycles and/or one or more deposition and curing steps as described herein.

As used herein, the term “low-k material layer” or “low-k material,” including “cured low-k material layer” and “cured low-k material” can refer to material whose dielectric constant is less than the dielectric constant of silicon dioxide or less than 4.0 or less than 3.8 or between about 2.5 and about 3.

As used herein, the term “structure” can refer to a partially or completely fabricated device structure. By way of examples, a structure can be a substrate or include a substrate with one or more layers and/or features formed thereon.

In this disclosure, “continuously” can refer to without breaking a vacuum, without interruption as a timeline, without any material intervening step, without changing conditions, immediately thereafter, as a next step, or without an intervening discrete physical or chemical structure between two structures other than the two structures in some embodiments and depending on the context.

A flowability (e.g., an initial flowability) can be determined as follows:

TABLE 1

| bottom/top | |
|---|---|
| ratio (B/T) | Flowability |
| 0 < B/T < 1 | None |
| 1 ≤ B/T < 1.5 | Poor |
| 1.5 ≤ B/T < 2.5 | Good |
| 2.5 ≤ B/T < 3.5 | Very good |
| 3.5 ≤ B/T | Extremely good |

where B/T refers to a ratio of thickness of film deposited at a bottom of a recess to thickness of film deposited at a top surface where the recess is formed, before the recess is filled. Typically, the flowability is evaluated using a wide recess having an aspect ratio of about 1:1 or less, since generally, the higher the aspect ratio of the recess, the higher the B/T ratio becomes. The B/T ratio generally becomes higher when the aspect ratio of the recess is higher. As used herein, a “flowable” film or material exhibits good or better flowability.

As set forth in more detail below, flowability of material can be temporarily obtained when one or more precursors are polymerized by, for example, excited species formed using a plasma. The resultant polymer material can exhibit temporarily flowable behavior. When a deposition step is complete and/or after a short period of time (e.g., about 3.0 seconds), the film may no longer be flowable, but rather becomes solidified.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments.

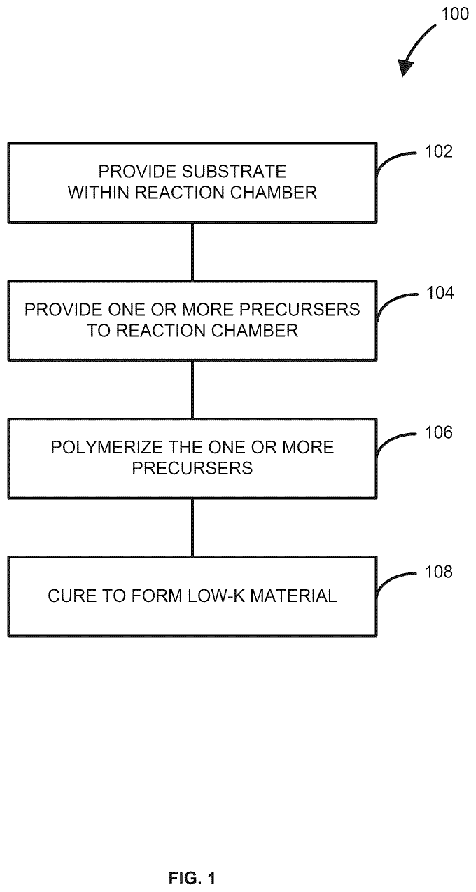

FIG. 1 illustrates a method 100 of forming a cured low-k material layer on a surface of a substrate in accordance with exemplary embodiments of the disclosure. Method 100 includes the step of providing a substrate within a reaction chamber (step 102), providing one or more precursors to the reaction chamber (step 104), providing plasma power to polymerize the one or more precursors within the reaction chamber (step 106), and curing the low-k material (step 108).

During step 102, a substrate is provided into a reaction chamber of a gas-phase reactor. In accordance with examples of the disclosure, the reaction chamber can form part of a chemical vapor deposition reactor, such as a plasma-enhanced chemical vapor deposition (PECVD) reactor or plasma-enhanced atomic layer deposition (PEALD) reactor. Various steps of methods described herein can be performed within a single reaction chamber or can be performed in multiple reaction chambers, such as reaction chambers of a cluster tool.

During step 102, the substrate can be brought to a desired temperature and/or the reaction chamber can be brought to a desired pressure, such as a temperature and/or pressure suitable for subsequent steps. By way of examples, a temperature (e.g., of a substrate or a substrate support) within a reaction chamber can be less than or equal to 450° C. or between about 340° C. and about 395° C. or about 250° C. and about 500° C.

During providing one or more precursors to the reaction chamber step 104, one or more precursors for forming low-k material are introduced into the reaction chamber. Exemplary precursors can include a compound comprising carbon and/or silicon. For example, the one or more precursors can include a compound comprising one or more of Si—C—Si and Si—O—Si bonds. The one or more precursors comprise a compound comprising a cyclic structure. The cyclic structure can include silicon. The cyclic structure can include silicon and oxygen. The one or more precursors can include a compound comprising an organosilicon compound. By way of particular examples, the one or more precursors comprise one or more of dimethyldimethoxysilane (DMDMOS), octamethylcyclotetrasiloxane (OMCTS), tetramethylcyclotetrasiloxane (TMCTS), octamethoxydodecasiloxane (OMODDS), octamethoxycyclioiloxane, dimethyldimethoxysilane (DM-DMOS), diethoxymethylsilane (DEMS), dimethoxymethylsilane (DMOMS), phenoxydimethylsilane (PODMS), dimethyldioxosilylcyclohexane (DMDOSH), 1,3-dimethoxytetramethyldisiloxane (DMOTMDS), dimethoxydiphenylsilane (DMDPS), and dicyclopentyldimethoxysilane (DcPDMS).

In some cases, the at least one of the one or more precursors comprises a ring structure comprising a chemical formula represented by —(Si(R₁,R₂)—O)ₙ—, where n ranges from about 3 to about 10. In accordance with examples, n=4 and R₁=R₂=CH₃; in accordance with further examples, n=4, R₁=H, and R₂=CH₃.

In accordance with further examples of the disclosure, at least one of the one or more precursors comprises a linear structure comprising a chemical formula represented by R₃—(Si(R₁,R₂)ₘ—O₍ₘ₋₁₎)—R₄, where m can range from about 1 to about 7. In accordance with examples, m=1, R₁=R₂=CH₃, and R₃=R₄=OCH₃; or m=2, R₁=R₂=CH₃, and R₃=R₄=OCH₃; or m=2, R₁=C₃H₆—NH₂, R₂=CH₃, and R₃=R₄=CH₃.

A flowrate of the one or more precursors to the reaction chamber can vary according to other process conditions. By way of examples, the flowrate can be from about 100 sccm to about 3,000 sccm or about 100 sccm to about 300 sccm. Similarly, a duration of each step of providing a precursor to the reaction chamber can vary, depending on various considerations. During steps 104 and/or 106, one or more inert gases can be provided to the reaction chamber. The one or more inert gases can be flowed to the reaction chamber at the same time or overlapping in time with the step of providing one or more precursors to the reaction chamber. Use of argon during steps 104/106 is thought to increase hardness of the cured low-k material layer.

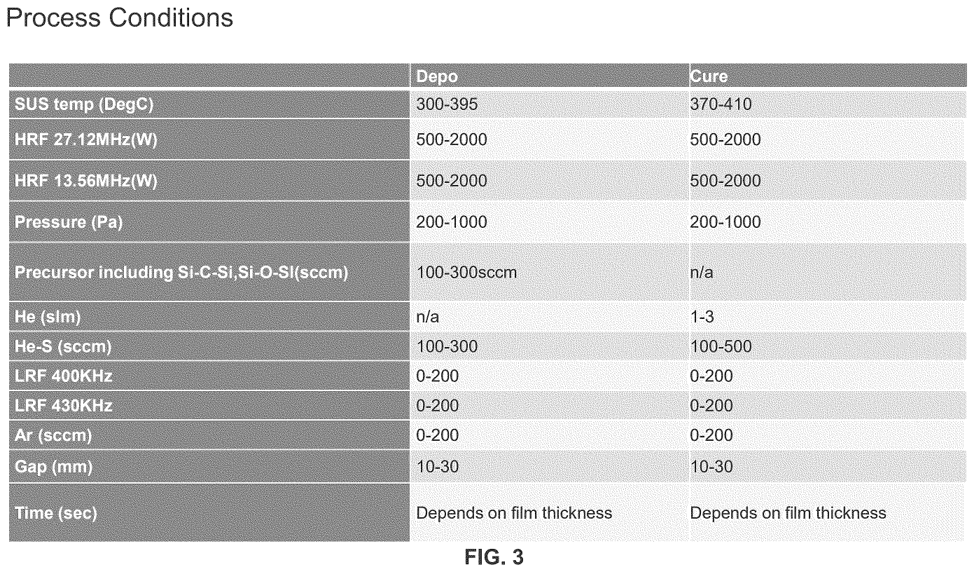

A temperature within the reaction chamber during step 104 can be between about 340° C. and about 395° C. or about 250° C. and about 500° C. A pressure within the reaction chamber during step 104 can be between about 700 Pa and about 900 Pa or about 200 Pa and about 1,000 Pa. Additional exemplary process conditions are provided in FIG. 3.

During step 106, the one or more precursors provided to the reaction chamber during step 104 are polymerized into the initially viscous material using excited species. The initially viscous material can become solid material—e.g., through further reaction with excited species and/or during curing step 108. Step 106 can include, for example, PECVD, PEALD, or PE cyclical CVD.

During step 106, a plasma can be generated using a direct plasma system, described in more detail below, and/or using a remote plasma system. A power used to generate the plasma during step 106 can be between about 500 W and about 2,000 W or about 600 W and about 2,500 W. A frequency of the power can range from 400 kHz and about 27.12 MHz or about 400 kHz and about 60 MHz, with single or dual (e.g., RF) power sources. In some cases, a frequency of power for step 106 can include a high RF frequency (e.g., over 1 MHz or about 13.56 MHz) and a low RF frequency (e.g., less than 500 kHz or about 430 kHz). The lower frequency power can be applied to either an anode or a cathode of a plasma generation system.

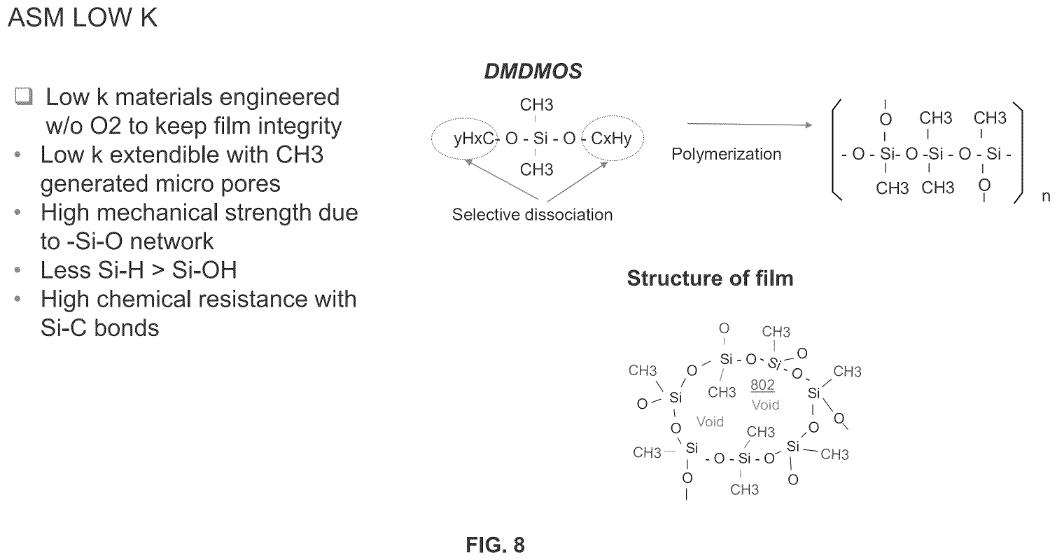

FIG. 8 illustrates an exemplary polymerization process for a particular precursor, DMDMOS. As illustrated, the polymerization can occur as a result of selective dissociation of molecule end groups (CₓH_{y} in the illustrative example). Further, the structure of the as deposited material or the cured low-k material layer may desirably include voids that form as the material polymerizes. The polymerize material can comprise, consist essentially or or consist of Ai, C, O, and H.

During step 108, curing the low-k material with activated species is used to form the cured low-k material layer. The curing can be done using an inert gas, such as one or more of helium, argon, nitrogen and neon. By way of examples, argon and/or helium can be used to form the activated species. In accordance with further examples, an oxidant is not provided during step 108.

One or more of a capacitively coupled plasma (CCP) excitation, RF frequency excitation, inductively coupled plasma (ICP) excitation, microwave excitation, and very high frequency (VHF) (e.g., VHF CCP) excitation of an inert gas can be used to form the activated species. By way of examples, VHF CCP can be used.

A temperature within the reaction chamber during step 108 can be between about 370° C. and about 410° C. or about 300° C. and about 500° C. A pressure within the reaction chamber during step 108 can be between about 300 Pa and about 800 Pa or about 200 Pa and about 1,000 Pa. A power to produce the plasma during step 108 can be between about 500 W and about 2,000 W or about 600 W and about 2,500 W. A frequency of the power to produce the activated species during step 108 can be between about 400 kHz and about 27.12 MHz or about 400 kHz and about 5 GHz. Additional exemplary process conditions are set forth in FIG. 3.

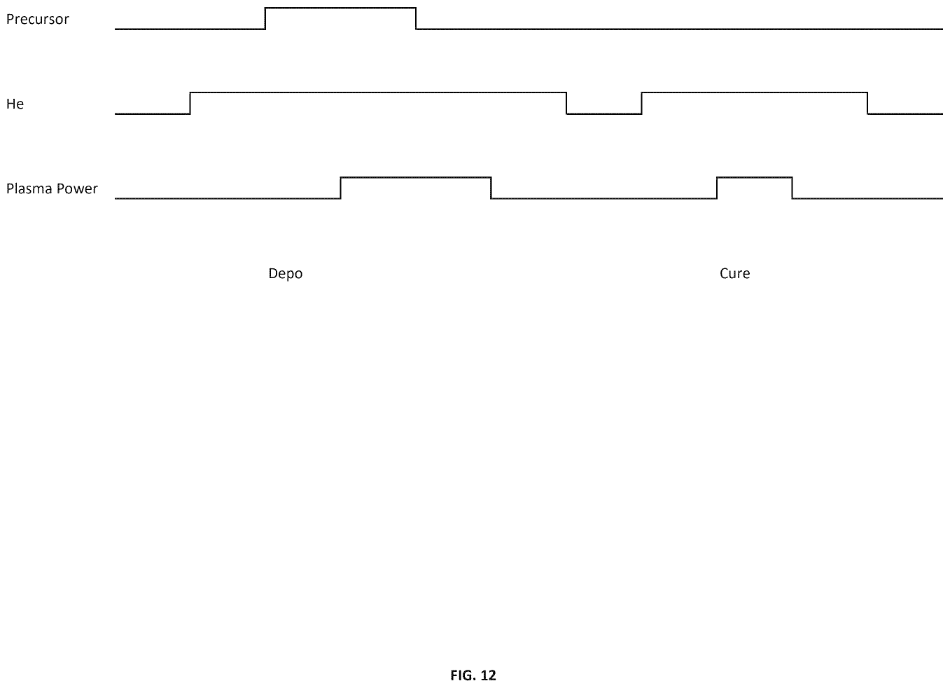

FIG. 12 illustrates a timing sequence diagram of an exemplary method, such as method 100, in accordance with examples of the disclosure. As illustrated, the method can begin with flowing an inert gas such as helium to the reaction chamber. The one or more precursors can then be introduced to the reaction chamber. In the illustrated example, after the precursor flow to the reaction chamber has started, a power to form the plasma is provided. The inert gas flow continues through the deposition process until after the power to form the plasma is turned off. If transferring chambers between a deposition process (“Depo”) and a cure process, the inert gas flow can be stopped, as illustrated. However, if performing the deposition and curing steps in the same reaction chamber, the flow of inert gas flow can be continuous through both steps.

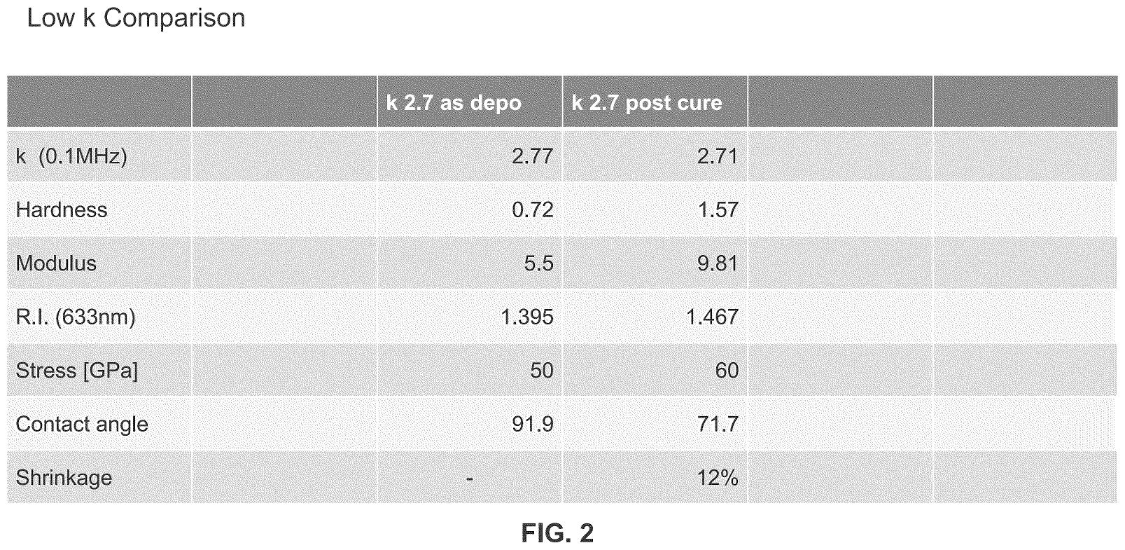

FIG. 2 illustrates properties of as deposited and cured low-k material layer formed in accordance with examples of the disclosure. As used herein, “as deposited” can refer to uncured or non-plasma cured material. As illustrated, the dielectric constant of the cured low-k material layer is lower than the dielectric constant of the as deposited low-k material. A hardness, elastic modulus, and refractive index of the low-k material layer is higher than the as deposited material.

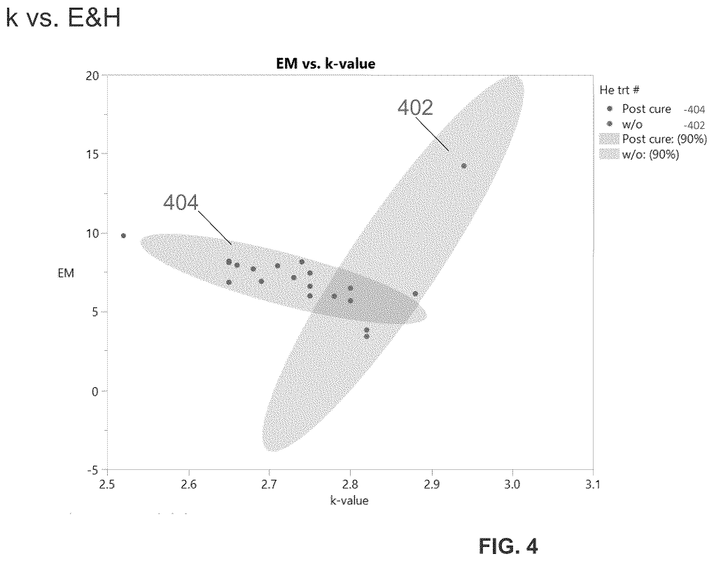

FIG. 4 illustrates elastic modulus and dielectric constant values for uncured low-k material 402 and cured low-k material layer 404 formed in accordance with examples of the disclosure.

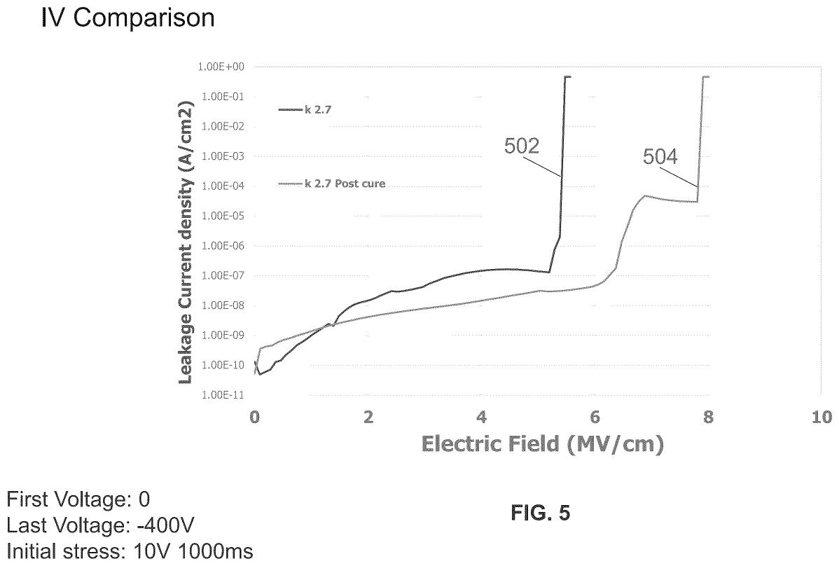

FIG. 5 illustrates leakage current density measurements and electric field measurements for as deposited material 502 and cured low-k material layer 504 formed in accordance with examples of the disclosure.

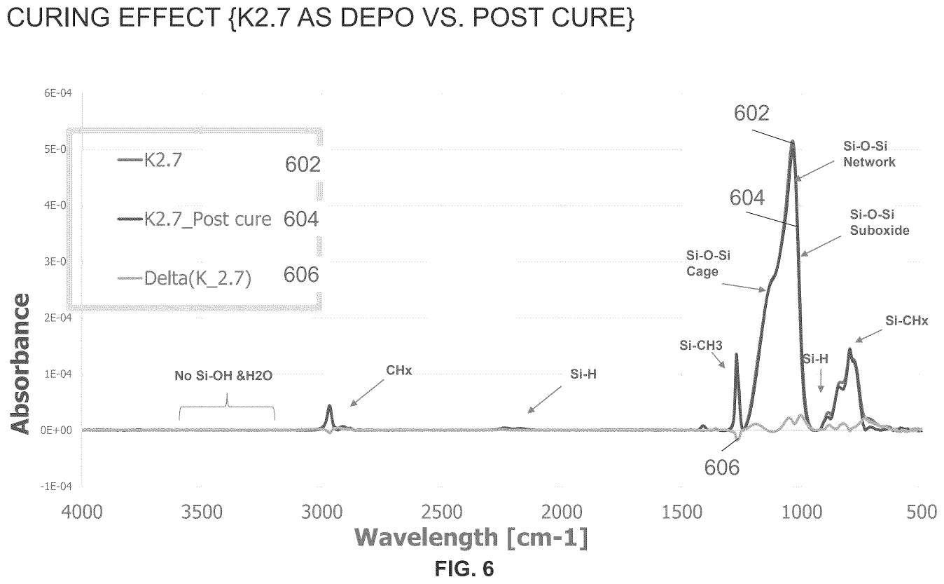

FIG. 6 illustrates effects of curing low-k material with activated species in accordance with examples of the disclosure. As illustrated, Si—CH₃ bonds were decreased for the cured low-k material layer data 604, relative to the uncured low-k material data 602. Line 606 represents a difference between data 602 and 604. It was observed that a decrease in Si—CH₃ bonds correlated to lower leakage current in the cured low-k material layers.

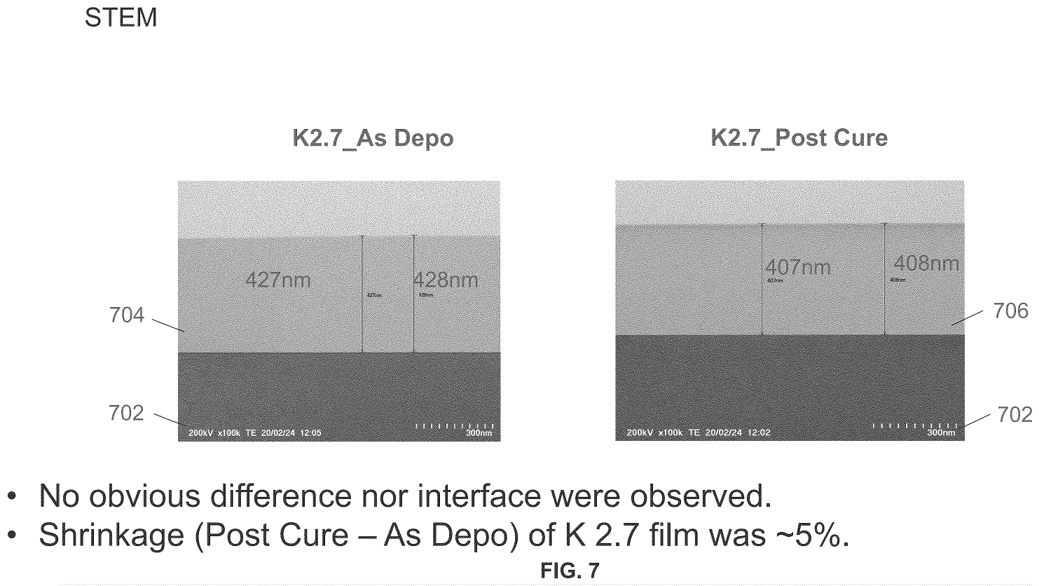

FIG. 7 illustrates structures in accordance with further examples of the disclosure. The structures include a substrate 702 and an as deposited low-k material 704 or a cured low-k material layer 706 formed overlying substrate 702. As illustrated, a shrinkage between the as deposited material and the cured low-k material layer was about five percent. No peeling or cracking was observed.

The structures illustrated in FIG. 7 can be formed using a method described herein, such as method 100. Cured low-k material layer 706 can exhibit a higher breakdown voltage than a breakdown voltage of the low-k material, an elastic modulus of the cured low-k material layer can be higher than a breakdown voltage of the low-k material, a hardness of the cured low-k dielectric material can be higher than a breakdown voltage of the low-k material, wherein the hardness is measured using a nanoindenter, and/or a dielectric constant of the cured low-k dielectric material is higher than a breakdown voltage of the low-k material, wherein the hardness is measured using a mercury probe.

Structures as described herein can be used to manufacture a variety of devices and/or for a variety of applications, including a shallow trench isolation layer for FET devices, including FinFET shallow trench isolation gap fill applications, gate all around nanowire device isolation gap fill applications, cross-point devices, memory or logic devices, and the like.

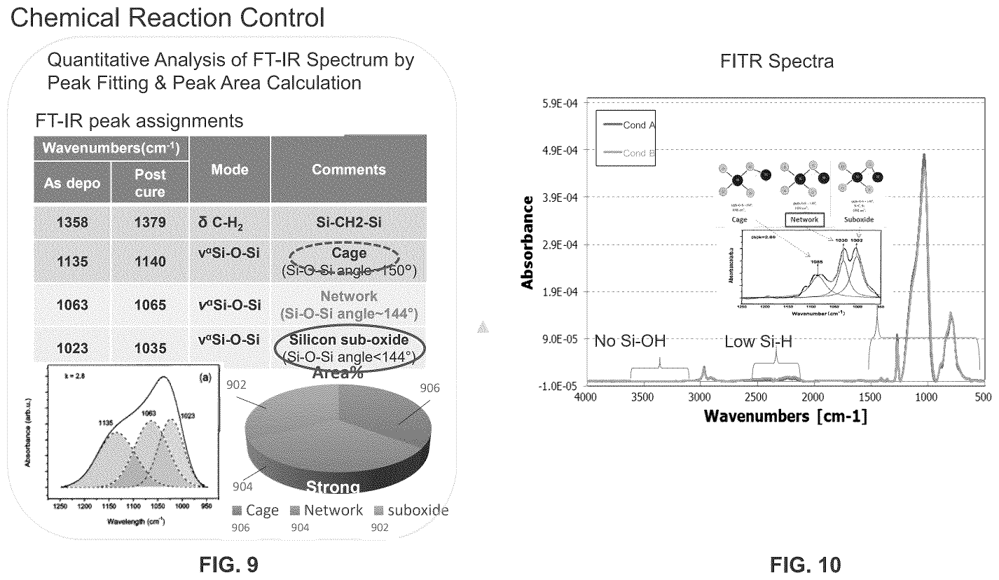

FIGS. 9 and 10 illustrate FTIR analysis of low-k material deposited and cured in accordance with examples of the disclosure.

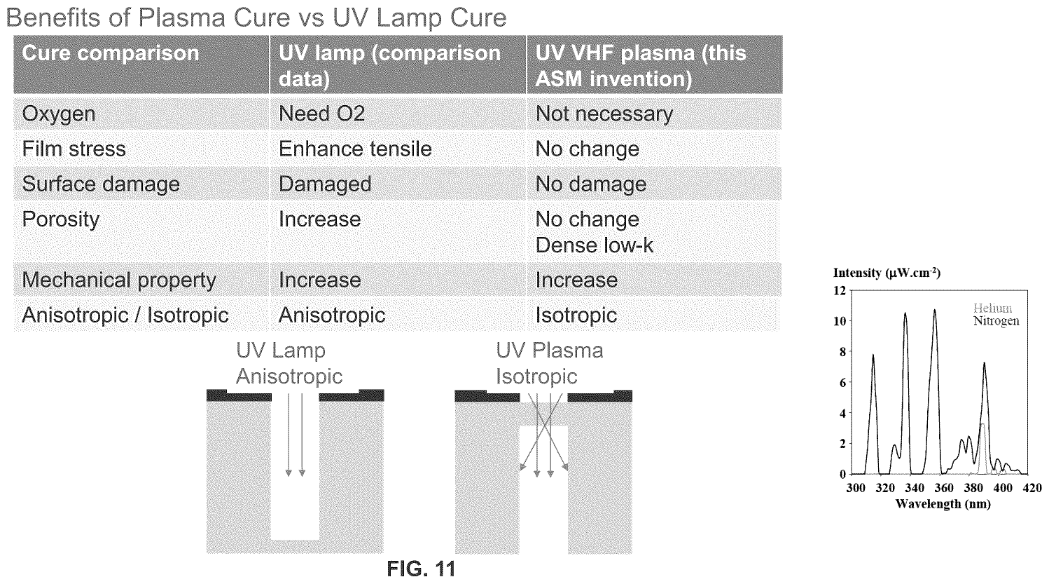

FIG. 11 illustrates benefits of plasma curing relative to curing using UV light. Cured low-k material layers formed in accordance with examples of the disclosure exhibit lower dielectric constant values, increased elastic module and hardness values, and no or relatively little change in film stress. Further, the films formed using a plasma cure process may be relatively dense compared to relatively porous material that can form with UC curing. Further, cured low-k material layers can exhibit increased moisture stability, comparted to UV cured material. Further, the plasma-cured layers may be less tensile stressed, compared to UV cured layers.

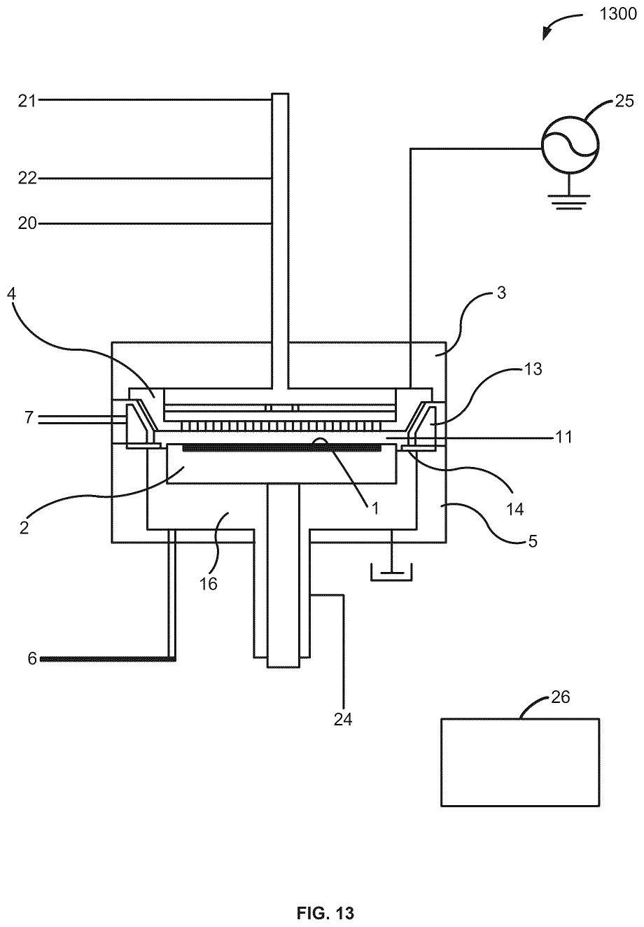

The cured low-k material layers can be formed using a PECVD reactor system, such as reactor system 1300, illustrated in FIG. 13. Reactor system 1300 can be used to perform one or more steps or sub steps as described herein and/or to form one or more structures or portions thereof as described herein.

Reactor system 1300 includes a pair of electrically conductive flat-plate electrodes 4, 2 in parallel and facing each other in the interior 11 (reaction zone) of a reaction chamber 3. A plasma can be excited within reaction chamber 3 by applying, for example, HRF power (e.g., 13.56 MHz or 27 MHz) and/or low frequency power from power source 25 to one electrode (e.g., electrode 4) and electrically grounding the other electrode (e.g., electrode 2). A temperature regulator can be provided in a lower stage 2 (the lower electrode), and a temperature of a substrate 1 placed thereon can be kept at a desired temperature. Electrode 4 can serve as a gas distribution device, such as a shower plate. Inert gas, precursor gas, and/or the like can be introduced into reaction chamber 3 using one or more of a gas line 20, a gas line 21, and a gas line 22, respectively, and through the shower plate 4. Although illustrated with three gas lines, reactor system 1300 can include any suitable number of gas lines.

In reaction chamber 3, a circular duct 13 with an exhaust line 7 is provided, through which gas in the interior 11 of the reaction chamber 3 can be exhausted. Additionally, a transfer chamber 5, disposed below the reaction chamber 3, is provided with a seal gas line 24 to introduce seal gas into the interior 11 of the reaction chamber 3 via the interior 16 (transfer zone) of the transfer chamber 5, wherein a separation plate 14 for separating the reaction zone and the transfer zone is provided (a gate valve through which a wafer is transferred into or from the transfer chamber 5 is omitted from this figure). The transfer chamber is also provided with an exhaust line 6. In some embodiments, the deposition and curing steps are performed in the same reaction space, so that two or more (e.g., all) of the steps can continuously be conducted without exposing the substrate to air or other oxygen-containing atmosphere. Performing the deposition and curing steps in the same reaction chamber can also increase throughput and/or decrease costs associated with forming the cured low-k material layers.

In some embodiments, continuous flow of an inert or carrier gas to reaction chamber 3 can be accomplished using a flow-pass system (FPS), wherein a carrier gas line is provided with a detour line having a precursor reservoir (bottle), and the main line and the detour line are switched, wherein when only a carrier gas is intended to be fed to a reaction chamber, the detour line is closed, whereas when both the carrier gas and a precursor gas are intended to be fed to the reaction chamber, the main line is closed and the carrier gas flows through the detour line and flows out from the bottle together with the precursor gas. In this way, the carrier gas can continuously flow into the reaction chamber, and can carry the precursor gas in pulses by switching between the main line and the detour line, without substantially fluctuating pressure of the reaction chamber.

A skilled artisan will appreciate that the apparatus includes one or more controller(s) 26 programmed or otherwise configured to cause one or more method steps as described herein to be conducted. The controller(s) are communicated with the various power sources, heating systems, pumps, robotics and gas flow controllers, or valves of the reactor, as will be appreciated by the skilled artisan.

In some embodiments, a dual chamber reactor (two sections or compartments for processing wafers disposed close to each other) can be used, wherein a reactant gas and a noble gas can be supplied through a shared line, whereas a precursor gas is supplied through unshared lines.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

What is claimed is:

1. A method of forming a cured low-k material layer on a surface of a substrate, the method comprising the steps of:
providing a substrate within a reaction chamber of a reactor system;
providing one or more precursors to the reaction chamber for a first time period;
providing plasma power to polymerize the one or more precursors within the reaction chamber to form low-k material; and
curing the low-k material with activated species to form the cured low-k material layer,
wherein the one or more precursors comprise one or more of octamethoxydodecasiloxane (OMODDS), dimethoxymethylsilane (DMOMS), phenoxydimethylsilane (PODMS), dimethyldioxosilylcyclohexane (DMDOSH), dimethoxydiphenylsilane (DMDPS), and dicyclopentyldimethoxysilane (DcPDMS).

2. The method of claim 1, wherein the one or more precursors consist of one or more of octamethoxydodecasiloxane (OMODDS), dimethoxymethylsilane (DMOMS), phenoxydimethylsilane (PODMS), dimethyldioxosilylcyclohexane (DMDOSH), dimethoxydiphenylsilane (DMDPS), and dicyclopentyldimethoxysilane (DcPDMS).

3. The method of claim 1, wherein providing plasma power is performed after the first time period.

4. The method of claim 1, wherein the activated species are formed from a gas consisting of an inert gas.

5. The method of claim 1, wherein a temperature in the reaction chamber during the step of curing is between 300° C. and 500° C.

6. The method of claim 4, wherein curing the low-k material comprises a very high frequency (VHF) excitation of the inert gas.

7. The method of claim 1, wherein the step of providing the inert gas begins prior to the step of providing the one or more precursors to the reaction chamber and is continuous until after the step of curing the low-k material.

8. The method of claim 1, wherein there is no intervening step between the step of providing plasma power to polymerize the one or more precursors and the step of curing the low-k material.

9. The method of claim 1, wherein the step of curing the low-k material lowers a dielectric constant, increases an elastic modulus of the low-k material, and increases a hardness of the low-k material.

10. The method of claim 1, wherein the step of curing increases a breakdown voltage of the low-k material, and lowers a leakage current density in the low-k material.

11. The method of claim 1, wherein the step of curing decreases Si—CH₃ bonds in the low-k material.

12. The method of claim 1, wherein the step of curing the low-k material with activated species comprises producing a plasma in the reaction chamber, wherein a power to produce the plasma during the step of curing the low-k material with activated species is between about 500 W and about 2,000 W or about 600 W and about 2,500 W.

13. The method of claim 1, wherein a power to produce the plasma during the step of providing plasma power to polymerize the one or more precursors is between about 500 W and about 2,000 W or about 600 W and about 2,500 W.

14. The method of claim 1, wherein the power to produce the plasma during the step of providing plasma power to polymerize the one or more precursors comprises a high frequency of greater than 1 MHz and a low frequency of less than 500 kHz.

15. The method of claim 1, wherein the substrate comprises one or more features having an aspect ratio of 1:1 or greater, and wherein the low-k material is formed within the one or more features.

16. The method of claim 1, wherein the plasma generated during the step of curing the low-k material is isotropic.

17. The method of claim 1, wherein the inert gas consists of helium.

18. The method of claim 1, wherein a temperature in the reaction chamber during the step of curing is between 370° C. and 410° C.

19. The method of claim 1, wherein a pressure within the reaction chamber during the step of curing the material with activated species is between about 300 Pa and about 800 Pa or about 200 Pa and about 1,000 Pa.

20. A method of forming a cured low-k material layer on a surface of a substrate, the method comprising the steps of:
providing a substrate within a reaction chamber of a reactor system;
providing an inert gas consisting essentially of helium and to the reaction chamber;
providing one or more precursors to the reaction chamber;
ceasing a flow of the one or more precursors to the reaction chamber;
after the step of ceasing, providing plasma power to polymerize the one or more precursors within the reaction chamber to form a low-k material; and
curing the low-k material with activated species formed from a gas consisting of the inert gas to form the cured low-k material layer, wherein a temperature in the reaction chamber during the step of curing is between 300° C. and 500° C.,
wherein the step of curing comprises use of very high frequency (VHF) excitation of the inert gas, wherein curing the low-k material comprises generating a plasma,
wherein the step of providing the inert gas begins prior to the step of providing the one or more precursors to the reaction chamber and is continuous until after the step of curing the low-k material,
wherein there is no intervening step between the step of providing plasma power to polymerize the one or more precursors and the step of curing the low-k material, and
wherein the step of curing the low-k material lowers a dielectric constant and increases an elastic modulus of the low-k material wherein the one or more precursors comprise one or more of octamethoxydodecasiloxane (OMODDS), dimethoxymethylsilane (DMOMS), phenoxydimethylsilane (PODMS), dimethyldioxosilylcyclohexane (DMDOSH), dimethoxydiphenylsilane (DMDPS), and dicyclopentyldimethoxysilane (DcPDMS).
